(19) United States
(12) Patent Application Publication
(10) Pub. No.: US 2012/0241761 A1
(43) Pub. Date: Sep. 27, 2012

(54) SEMICONDUCTOR DEVICE AND METHOD FOR MANUFACTURING SAME

(75) Inventor: Hidetoshi ASAHARA, Kanagawa-ken (JP)

(73) Assignee: Kabushiki Kaisha Toshiba, Tokyo (JP)

(21) Appl. No.: 13/239,114

(22) Filed: Sep. 21, 2011

(30) Foreign Application Priority Data
Mar. 25, 2011 (JP) 2011-067631

(51) Int. Cl. H01L 29/78; H01L 21/336; H01L 29/24

(52) U.S. Cl. 257/77; 257/331; 438/270; 257/E29.262; 257/E29.104; 257/E21.41

(57) ABSTRACT

According to an embodiment, a semiconductor device includes a first semiconductor layer of a first conductive type, a first main electrode provided on a first major surface side of the first semiconductor layer, and a second main electrode provided on a second major surface side of the first semiconductor layer. A pair of first control electrodes is provided within a trench provided from the first major surface side to the second major surface in the first semiconductor layer; and the first control electrodes are provided separately from each other in a direction parallel to the first major surface. Each of the first control electrodes faces an inner face of the trench via a first insulating film. A second control electrode is provided between the first control electrodes and a bottom face of the trench, and faces the inner face of the trench via a second insulating film.

### CROSS-REFERENCE TO RELATED APPLICATIONS

This application is based upon and claims the benefit of priority from Japanese Patent Application No. 2011-67631, filed on Mar. 25, 2011; the entire contents of which are incorporated herein by reference.

### FIELD

Embodiments are generally related to a semiconductor device and a method for manufacturing the same.

### BACKGROUND

A semiconductor device for power control is widely used as a key device in power electronics. The semiconductor device has a different configuration suitable for each use. For example, in the use requiring high-speed switching, high resisting pressure and low ON-resistance as well as reduction of a gate-source capacitance as an input capacitance are required.

In contrast, in order to reduce the ON-resistance of the power semiconductor device, a trench gate configuration is widely used. Then, in the trench gate configuration, by providing a source electrode in addition to a gate electrode within one trench, high resisting pressure and low ON-resistance characteristics can be achieved. However, by providing the gate electrode and the source electrode within the trench close to each other, a parasitic capacitance between the gate and the source increases. Therefore, there is a demand for a semiconductor device which can reduce the gate-source capacitance in the trench configuration and a convenient method for realizing the semiconductor device.

### BRIEF DESCRIPTION OF THE DRAWINGS

FIG. 1 is a schematic cross-sectional view illustrating a semiconductor device according to a first embodiment;

FIGS. 2A to 6B are partial cross-sectional views schematically illustrating manufacturing processes of the semiconductor device according to the first embodiment;

FIG. 7 is a schematic cross-sectional view illustrating a semiconductor device according to a variation of the first embodiment;

FIG. 8 is a schematic cross-sectional view illustrating a semiconductor device according to a second embodiment;

FIG. 9 is a schematic cross-sectional view illustrating a semiconductor device according to a third embodiment.

### DETAILED DESCRIPTION

In general, according to an embodiment, a semiconductor device includes a first semiconductor layer of a first conductive type, a first main electrode provided on a first major surface side of the first semiconductor layer, and a second main electrode provided on a second major surface side of the first semiconductor layer. A pair of first control electrodes is provided within a trench provided from the first major surface side to the second major surface in the first semiconductor layer; and the first control electrodes are provided separately from each other in a direction parallel to the first major surface. Each of the first control electrodes faces an inner face of the trench via a first insulating film. A second control electrode is provided between the first control electrodes and a bottom face of the trench, and faces the inner face of the trench via a second insulating film.

Hereinafter, embodiments will be described with reference to the accompanying drawings. In the following embodiments, like components are marked with like reference numerals, detailed description thereof is appropriately omitted and differences are described. Although a first conductive type is an n-type and a second conductive type is a p-type in the following examples, the first conductive type may be the p-type and the second conductive type may be the n-type.

### First Embodiment

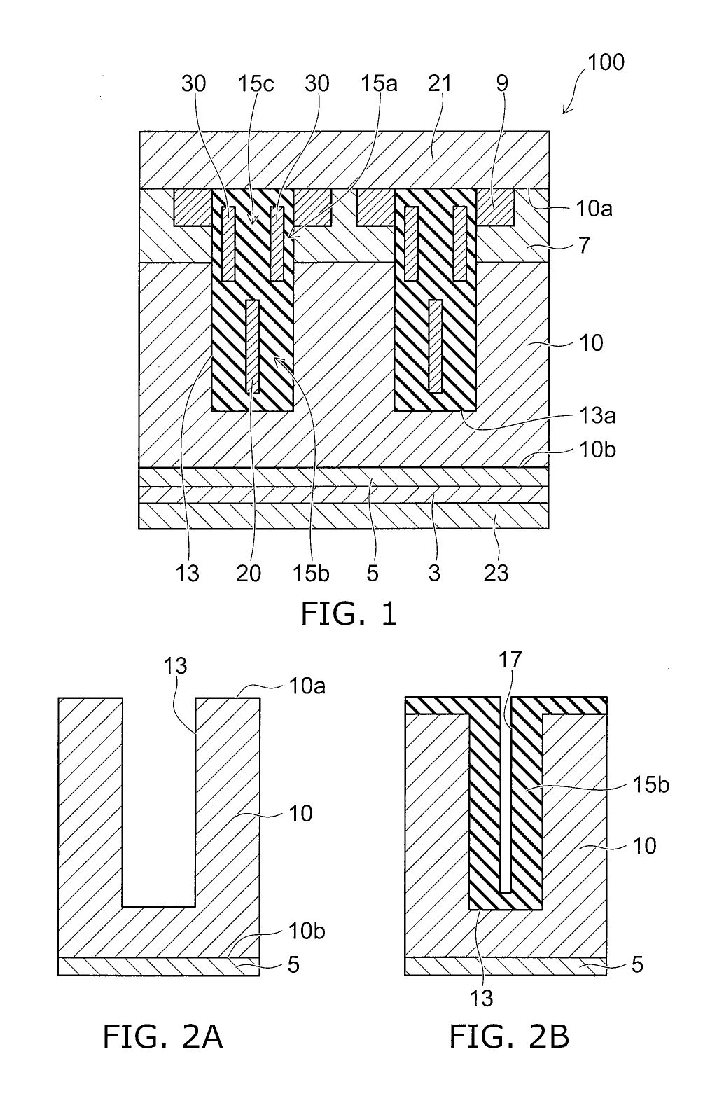

FIG. 1 is a schematic view showing a cross-sectional configuration of a semiconductor device 100 according to the embodiment. The semiconductor device 100 exemplified herein is a power MOSFET having the trench gate configuration.

The semiconductor device 100 includes a n-type drift layer 10 as a first semiconductor layer. The n-type drift layer 10 is provided, for example, on an n-type silicon substrate 3 via an n-type drain layer 5 (a third semiconductor layer). A p-type base region 7 as a first semiconductor region is provided in a surface of the n-type drift layer on the side of a first major surface 10a. Furthermore, an n-type source region 9 as a second semiconductor region is provided on a surface of the p-type base region 7.

A source electrode 21 as a first main electrode is provided on the side of the first major surface 10a of the n-type drift layer 10. The source electrode 21 is electrically connected to the p-type base region 7 and the n-type source region 9.

In contrast, a drain electrode 23 as a second main electrode is provided on the side of a second major surface 10b of the n-type drift layer 10. The drain electrode 23 is provided, for example, in contact with a back face of the n-type silicon substrate 3 and is electrically connected to the n-type drift layer 10 via the n-type silicon substrate 3 and the n-type drain layer 5.

A trench 13 is formed from the side of the first major surface 10a of the n-type drift layer 10 toward the second major surface 10b. The trench 13 is provided so as to penetrate the p-type base region 7 from the surface of the n-type source region 9 and reach the n-type drift layer 10. A pair of gate electrodes 30 as first control electrodes and a field electrode 20 as a second control electrode are provided within the trench 13.

As shown in FIG. 1, the two gate electrodes 30 are provided separately from each other in a direction parallel to the first major surface 10a and each of the gate electrodes 30 faces an inner face of the trench via a gate insulating film 15a as a first insulating film. A drain current flows between the drain electrode 23 and the source electrode 21 via an inverting channel formed between the p-type base region 7 and the gate insulating film 15a. Hence, a gate voltage applied to the gate electrodes 30 controls the drain current.

Within the trench 13, the field electrode 20 is provided between the two gate electrodes 30 and a bottom face 13a of the trench 13 on the side of the second major surface 10b. The field electrode 20 faces the inner face of the trench 13 via a field insulating film 15b as a second insulating film.

For example, a part of the field electrode 20 (not shown) is electrically connected to the source electrode 21. Thereby, it becomes possible to mitigate an electric field concentration induced between a p-type base layer 7 and the n-type drift layer 10 and to raise the breakdown voltage between the source electrode 21 and the drain electrode 23.

Furthermore, in order to improve the breakdown voltage between the n-type drift layer 10 and the field electrode 20, the thickness of the field insulating film 15b formed between the inner face of the trench 13 and the field electrode 20 is increased. That is, the thickness of the field insulating film 15b in the direction parallel to the first major surface 10a is greater than the thickness of the gate insulating film 15a in the direction parallel to the first major surface 10a.

Next, with reference to FIGS. 2 to 6, manufacturing processes of the semiconductor device 100 will be described below. FIGS. 2 to 6 are schematic views showing a partial cross section of the semiconductor device in the vicinity of the trench 13 in each process.

First, as shown in FIG. 2A, the trench 13 is formed from the first major surface 10a of the n-type drift layer 10 formed on the n-type drain layer 5 toward the second major surface 10b. The trench 13 is provided in a stripe shape along the first major surface 10a, for example, using a RIE (Reactive Ion Etching) method.

For example, each of the n-type drain layer 5 and the n-type drift layer 10 is a silicon epitaxial layer formed on the n-type silicon substrate 3 (refer to FIG. 1). The concentration of n-type impurities contained in the n-type drift layer 10 is lower than the concentration of n-type impurities contained the n-type drain layer 5. Moreover, the n-type drift layer 10 may be formed directly on the n-type silicon substrate without forming the n-type drain layer 5.

Next, as shown in FIG. 2B, the field insulating film 15b is formed by thermally oxidizing the inner face of the trench 13. A gap 17 is left within the trench 13 for forming the field electrode 20. The field insulating film 15b is a so-called silicon thermal oxide film, that is, a silicon dioxide film (SiO₂ film).

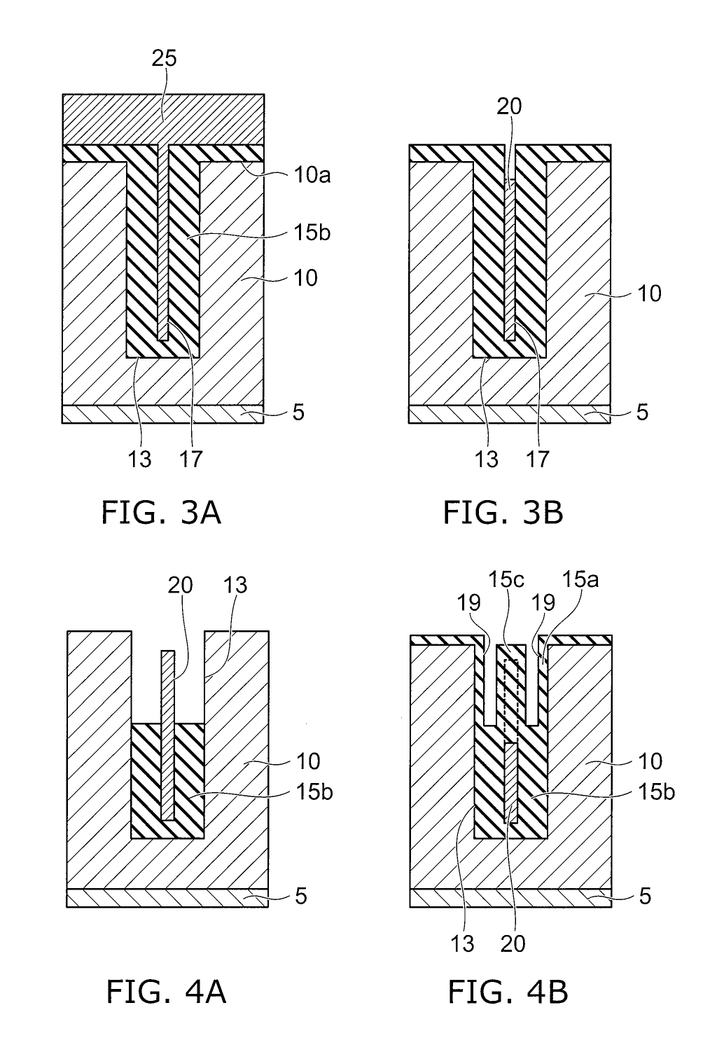

Subsequently, as shown in FIG. 3A, a polycrystalline silicon (polysilicon) film 25 is formed on the side of the major surface 10a of the n-type drift layer 10 to fill the gap 17 of the trench 13. The polysilicon film 25 is a conductive film doped with, for example, boron (B) as a p-type impurity, at a high concentration and can be formed using a low pressure CVD (Chemical Vapor Deposition) method.

Subsequently, as shown in FIG. 3B, the polysilicon film 25 formed on the surface of the n-type drift layer 10 is removed by etching, except for the part in which the gap 17 has been filled. Thereby, the field electrode 20 is formed with the conductive polysilicon film.

Then, as shown in FIG. 4A, the field insulating film 15b is etched back to an intermediate position between the first major surface 10a of the n-type drift layer 10 and the end of the field electrode 20 on a bottom face side of the trench 13.

Subsequently, as shown in FIG. 4B, a wall face exposed on an upper part of the trench 13 and the field electrode 20 are thermally oxidized. Thereby, the gate insulating film 15a is formed on the wall face of the trench 13, and an insulating layer (SiO₂ film) 15c, which is an oxidized part of the field electrode 20, is formed within the trench 13. Then, a gap 19 is left between the gate insulating film 15a and the insulating layer 15c for forming the gate electrode 30. The gate insulating film 15a is a silicon oxide film (SiO₂ film).

In the above-mentioned thermal oxidizing process, while the gate insulating film 15a is formed so as to have a predetermined thickness on the wall face of the trench 13, the field electrode 20 is completely oxidized. That is, it is preferable to use an oxidizing condition in which the oxidizing speed of the polysilicon doped with a high concentration impurities is faster than the oxidizing speed of the n-type drift layer 10 as a single-crystalline silicon layer.

Next, the gate electrode 30 is formed within the trench 13 in which the field insulating film 15b has been etched back, that is, in the gap 19.

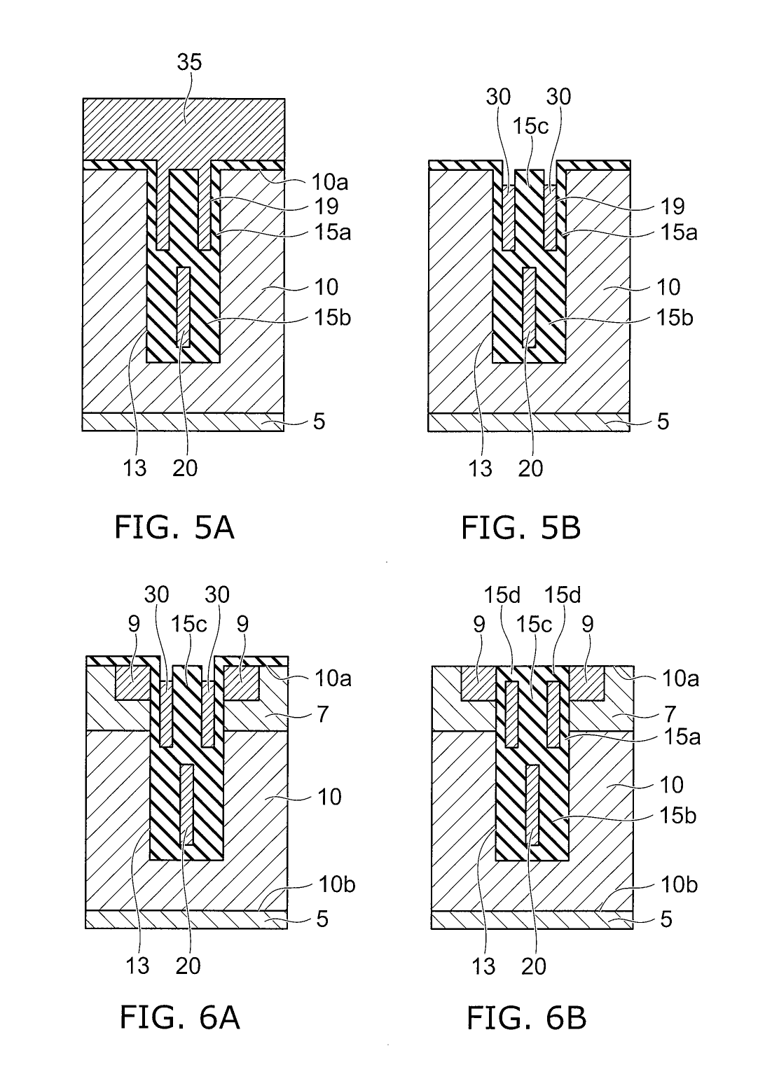

As shown in FIG. 5A, for example, a conductive polysilicon film 35 is formed on the side of the major surface 10a of the n-type drift layer 10 to thereby fill the gap 19. Subsequently, as shown in FIG. 5B, the polysilicon film 35 is etched except for the part filling the gap 19. Thereby, the pair of the gate electrodes 30 across the insulating layer 15c is formed in the upper part of the trench 13.

Then, as shown in FIG. 6A, the p-type base region 7 and the n-type source region 9 are formed on the surface of the n-type drift layer 10. The p-type base region 7 is formed, for example, by ion-implanting boron (B) as the p-type impurity into the surface of the n-type drift layer 10, performing thermal treatment, and diffusing the ions toward the second major surface 10b. The n-type source region 9 is formed, for example, by ion-implanting arsenic (As) as the n-type impurity into the surface of the p-type base region 7.

Subsequently, as shown in FIG. 6B, a space above the gate electrodes 30 is filled with an insulating film and further, surfaces of the p-type base region 7 and the n-type source region 9 are exposed. Then, the source electrode 21 is formed on the side of the first major surface 10a of the n-type drift layer 10, and the drain electrode 23 is formed on the side of second major surface 10b of the n-type drift layer 10 to thereby complete the semiconductor device 100.

The semiconductor device 100 according to the embodiment includes the pair of the gate electrodes 30 and the field electrode 20 within the trench 13. The field electrode 20 is electrically connected to, for example, the source electrode 21, thereby raising the breakdown voltage between the drain and the source. The insulating layer 15c is provided between the gate electrodes 30 and the field electrode 20. Thereby, the parasitic capacitance between the source and the gate can be reduced, and switching speed can be improved.

The field electrode 20 may not only be connected to the source electrode 21, but also be electrically connected to, for example, gate electrodes 30. In this case, in an ON-state in which a positive voltage is applied to the gate electrode, an n-type accumulating layer is formed on an interface between the n-type drift layer 10 and the field insulating film 15b, and thus the ON-resistance can be reduced.

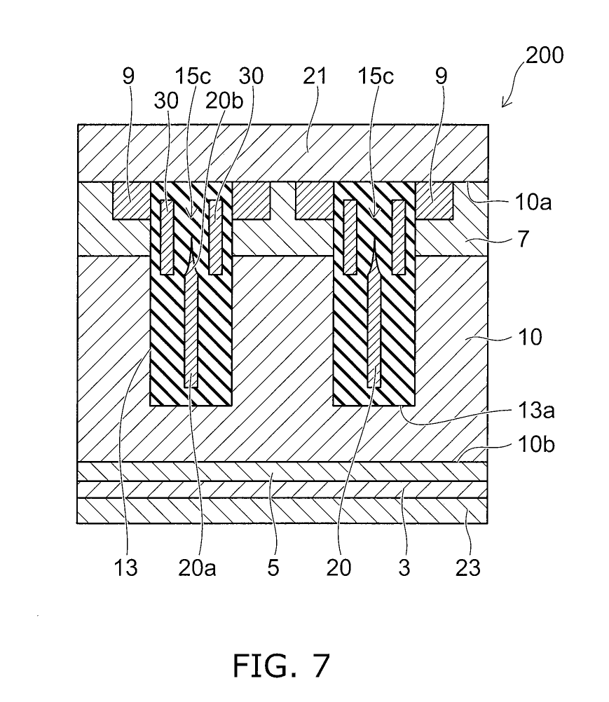

Next, with reference to FIG. 7, a semiconductor device 200 according to a variation of the first embodiment will be described. As shown in FIG. 7, the semiconductor device 200 is different from the semiconductor device 100 shown in FIG. 1 in that the end of the field electrode 20 on the side of the first major surface 10a extends between the two gate electrodes 30.

That is, in the semiconductor device 200, the field electrode 20 has a first part 20a provided between the gate electrodes 30 and the bottom face of the trench 13 and a second part 20b extending between the two gate electrodes 30. The width of the second part 20b in the direction parallel to the first major surface 10a is smaller than the width of the first part 20a in the direction parallel to the first major surface 10a.

Such a configuration is formed, for example, in the case where the exposed part of the field electrode 20 is not completely oxidized in the thermal oxidizing process shown in FIG. 4B. Also in the semiconductor device 200, providing the insulating layer 15c through thermal oxidation of the field electrode 20 reduces the parasitic capacitance between the field electrode 20 and the gate electrodes 30. Thereby, the switching speed can be improved.

### Second Embodiment

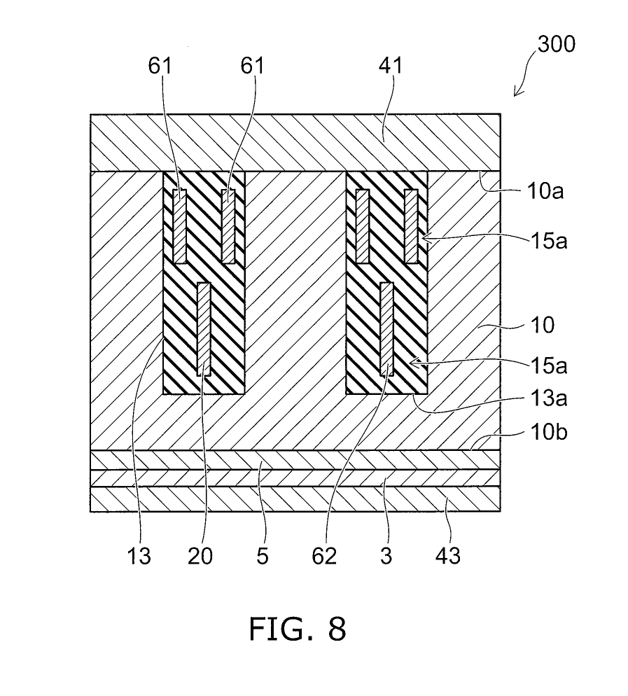

FIG. 8 is a schematic view showing a cross-sectional configuration of a semiconductor device 300 according to the second embodiment. The semiconductor device 300 is a Schottky barrier diode (SBD) having a trench gate configuration including gate electrodes 61 and a field electrode 62 as the second control electrode.

As shown in FIG. 8, the semiconductor device 300 includes the n-type drift layer 10, an anode electrode 41 as the first main electrode provided on the side of the first major surface 10a of the n-type drift layer 10, and a cathode electrode 43 as the second main electrode provided on the side of the second major surface 10b. Schottky junction is formed between the anode electrode 41 and the n-type drift layer 10.

Then, the trench 13 is formed from the side of the first major surface 10a of the n-type drift layer 10 toward the second major surface 10b. A pair of the gate electrodes 61 and the field electrode 62 are provided within the trench 13. The field electrode 62 is provided between the gate electrodes 61 and the bottom face 13a in the trench 13. The gate electrodes 61 are provided separately from each other in the direction parallel to the first major surface 10a and each of the gate electrodes 61 faces the inner face of the trench 13 via the gate insulating film 15a. The field electrode 62 faces the inner face of the trench via the insulating film 15b.

In the semiconductor device 300, for example, parts of the gate electrodes 61 and the field electrode 62 (not shown) are electrically connected to the anode electrode 41. In an ON-state in which, for example, forward bias is applied between the anode and the cathode, a positive voltage is applied to the gate electrodes 61 and the field electrode 62, and an n-type accumulating layer is formed between the n-type drift layer 10 and the gate insulating film 15a and between the n-type drift layer 10 and the insulating film 15b. Thereby, the ON-resistance can be reduced. Furthermore, in an OFF state in which reverse bias is applied between the anode and the cathode, a negative voltage is applied to the gate electrodes 61 and the field electrode 62, and a depletion region is formed in the n-type drift layer 10, extending from an interface between the n-type drift layer 10 and the gate insulating film 15a and an interface between the n-type drift layer 10 and the insulating film 15b. Thereby, in an OFF state, the breakdown voltage can be increased between the anode electrode 41 and the cathode electrode 43, and thus a leak current can be reduced.

### Third Embodiment

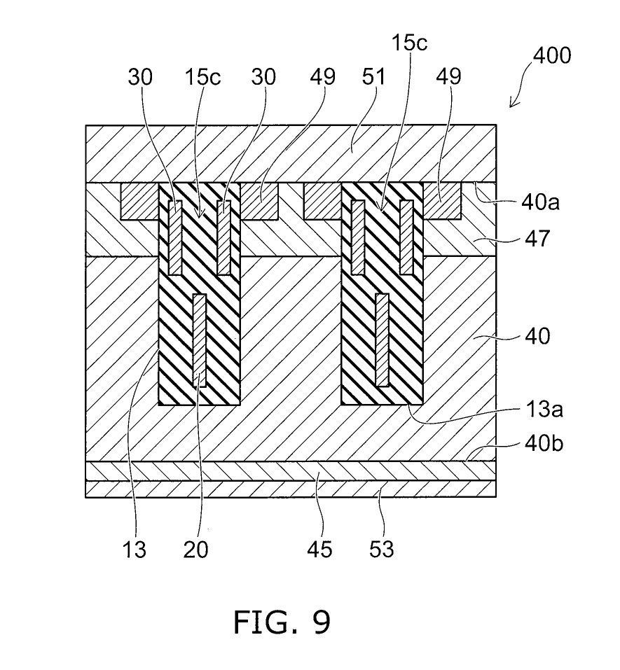

FIG. 9 is a schematic view showing a cross-sectional configuration of a semiconductor device 400 according to the third embodiment. The semiconductor device 400 is different from the semiconductor device 100 shown in FIG. 1 in that the semiconductor device 400 is an IGBT (Insulated Gate Bipolar Transistor) having the trench gate configuration and includes a p-type collector layer 45 as a second semiconductor layer and a collector electrode 53 on the side of a second major surface 40b of an n-type base layer 40.

In the semiconductor device 400, the trench gate configuration including the field electrode 20, a pair of the gate electrodes 30, a p-type base region 47, an n-type emitter region 49 and an emitter electrode 51 are provided on the side of a first major surface 40a of the n-type base layer 40 as the first semiconductor layer. After that, on the side of the second major surface 40b, the n-type silicon substrate 3 is removed and, for example, the p-type collector layer 45 is provided by ion-implanting the p-type impurities. Then, the collector electrode 53 connected to the p-type collector layer is provided.

As shown in FIG. 9, the trench 13 provided on the side of the first major surface 40a of the n-type base layer 40 includes the gate electrodes 30 and the field electrode 20. The insulating layer 15c formed by thermally oxidizing a part of the field electrode 20 is provided between the two gate electrodes. Then, field electrode 20 is arranged between the gate electrodes 30 and the bottom face 13a of the trench 13. Thereby, for example, in the case where the field electrode 20 is electrically connected to the emitter electrode 51, it is possible to reduce the parasitic capacitance between the gate and the emitter and improve the switching speed.

Although the first to the third embodiments of the invention have been described, the invention can be also applied to other semiconductor devices having the trench gate configuration. Furthermore, the material for the semiconductor device is not limited to silicon, and, for example, silicon carbide (SiC) and the like can be used as the material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer of a first conductive type;
a first main electrode provided on a first major surface side of the first semiconductor layer;
a second main electrode provided on a second major surface side of the first semiconductor layer;
a pair of first control electrodes provided within a trench provided from the first major surface side to the second major surface in the first semiconductor layer, the first control electrodes being provided separately from each other in a direction parallel to the first major surface, each of the first control electrodes facing an inner face of the trench via a first insulating film; and
a second control electrode provided between the first control electrodes and a bottom face of the trench, and facing the inner face of the trench via a second insulating film.

2. The device according to claim 1, wherein a thickness of the second insulating film in the direction parallel to the first major surface is greater than a thickness of the first insulating film in a direction parallel to the first major surface.

3. The device according to claim 1, wherein
the second control electrode has a first part provided between the first control electrodes and the bottom face, and a second part extending between the first control electrodes, and
the width of the second part in a direction parallel to the first major surface is smaller than the width of the first part in the direction parallel to the first major surface.

4. The device according to claim 1, further comprising
a first semiconductor region of a second conductive type provided in a surface of the semiconductor layer on the first major surface side, and
a second semiconductor region of the first conductive type selectively provided on the surface of the first semiconductor region,
wherein the first main electrode is electrically connected to the first semiconductor region and the second semiconductor region.

5. The device according to claim 1, further comprising a second semiconductor layer of the second conductivity type provided between the first semiconductor layer and the second main electrode.

6. The device according to claim 1, wherein the second control electrode is electrically connected to the first main electrode.

7. The device according to claim 1, wherein the first control electrodes are electrically connected to the second control electrode.

8. The device according to claim 1, wherein the second control electrode includes polycrystalline silicon containing second conductive type impurities.

9. The device according to claim 1, wherein
Schottky junction is provided between the first semiconductor layer and the first main electrode, and
the first control electrodes, the second control electrode and the first main electrode are electrically connected to one another.

10. The device according to claim 1, wherein an insulating layer is provided between the first control electrodes, and between the first control electrodes and the second control electrode.

11. The device according to claim 1, wherein the first control electrodes and the second control electrode are provided within the stripe-shaped trench extending along the first major surface.

12. The device according to claim 1, wherein a third semiconductor layer is provided between the first semiconductor layer and the second main electrode; and the third semiconductor layer contains first conductive type impurities of higher concentration than a concentration of the first impurities in the first semiconductor layer.

13. The device according to claim 1, wherein
the first semiconductor layer contains silicon; and
each of the first insulating film and the second insulating film is a silicon oxide film.

14. The device according to claim 13, wherein the first semiconductor layer is a silicon epitaxial layer provided on a silicon substrate.

15. The device according to claim 13, wherein the semiconductor layer is a silicon carbide layer.

16. A method for manufacturing a semiconductor device comprising:
forming a first insulating film on an inner face of a trench using thermally oxidizing method, the trench being formed in a first semiconductor layer of a first conductive type on a first major surface side of the first semiconductor layer;
filling inside of the trench with polycrystalline silicon;
etching back the first insulating film to an intermediate position between the first major surface and an end of the polycrystalline silicon on a bottom face side of the trench;
thermally oxidizing the polycrystalline silicon exposed by the etching-back; and
forming a first control electrode in the etched-back space of the trench.

17. The method according to claim 16, wherein the inner face of the trench is thermally oxidized in the process of thermally oxidizing the polycrystalline silicon, and the oxidizing speed of the inner face of the trench is lower than the oxidizing speed of the polycrystalline silicon.

18. The method according to claim 16, wherein the first control electrode includes polycrystalline silicon.

19. The method according to claim 16, wherein
the first semiconductor layer contains silicon, and
a silicon oxide film is formed on the inner face of the trench by using the thermally oxidizing method.

20. The method according to claim 16, further comprising:
forming a first semiconductor region of a second conductive type in a surface of the first semiconductor layer on a first major surface side, and
selectively forming a second semiconductor region of the first conductive type on the surface of the first semiconductor region.
